(19) United States
(12) Patent Application Publication
(10) Pub. No.: US 2011/0169080 A1
(43) Pub. Date: Jul. 14, 2011

(54) CHARGE BALANCE POWER DEVICE AND MANUFACTURING METHOD THEREOF

(76) Inventors: Chong-Man YUN, Seoul (KR); Soo-Seong Kim, Seoul (KR); Kwang-Hoon Oh, Seoul (KR)

(21) Appl. No.: 12/967,580

(22) Filed: Dec. 14, 2010

(30) Foreign Application Priority Data
Jan. 12, 2010 (KR) 10-2010-0002528

(51) Int. Cl. H01L 29/78; H01L 21/336

(52) U.S. Cl. 257/341; 438/269; 257/E29.262; 257/E21.41

(57) ABSTRACT

A charge-balance power device and a method of manufacturing the charge-balance power device are provided. The charge-balance power device includes: a charge-balance body region in which one or more first conductive type pillars as a first conductive type impurity region and one or more second conductive type pillars as a second conductive type impurity region are arranged; a first conductive type epitaxial layer that is formed on the charge-balance body region; and a transistor region that is formed in the first conductive type epitaxial layer. With this invention, it is possible to form the same charge-balance body region regardless of the structure of the transistor region formed on the top side of wafer.

### CROSS REFERENCE

This application is based on and claims priority under 35USC 119 from Korean Patent Application No. 10-2010-0002528, filed on Jan. 12, 2010.

### BACKGROUND

1. Field of the Invention

The present invention relates to a semiconductor device, and more particularly, to a charge-balance power device and a manufacturing method thereof.

2. Description of the Related Art

Semiconductor devices such as MOSFET (Metal-Oxide Semiconductor Field Effect Transistor) or IGBT (Insulated Gate Bipolar Transistor) are often used as semiconductor switching devices in the field of power electronics applications. That is, such semiconductor devices are used as semiconductor switching devices in the field of power electronics applications such as H-bridge inverters, half-bridge inverters, three-phase inverters, multi-level inverters, and converters.

In general, a power MOSFET used in the field of power electronics applications have a structure in which electrodes are disposed in two planes opposed to each other. That is, a source electrode and a drain electrode are disposed on the front surface and the rear surface of a semiconductor body, respectively, and a gate insulating film and a gate electrode are formed on the front surface of the semiconductor body adjacent to the source electrode.

When the semiconductor device is turned on, drift current flows in the vertical direction in the semiconductor device. When the semiconductor device is turned off, depletion regions extending in the horizontal direction due to an inverse bias voltage applied to the semiconductor device are formed in the semiconductor device.

To obtain a higher breakdown voltage, the resistivity and the thickness of a drift layer disposed between the electrodes have to be increased. However, this causes an increase in on-resistance of the device which reduces the conductivity and the device switching speed, thereby results in an inferior device performance.

To solve this problem, a charge-balance power device has been proposed which has a drift region that includes n regions and p regions (p pillars), extending vertically and with alternating n and p regions.

One shortcoming of this type of charge-balance power devices is that devices with the same breakdown voltage but different current ratings, different charge-balance body regions are required dependent on the design of the transistor region.

The foregoing discussion on the related art is technical information of the inventor acquired either prior to or in the course of making the invention, and cannot be said to be technical information known to the public before the filing of this application.

### SUMMARY

One advantage of some aspects of the invention is that it provides charge-balance power devices having the same charge-balance body region regardless of the structure of the transistor region formed on the top side of wafer with the breakdown voltage and a method of manufacturing such charge-balance power devices.

Another advantage of some aspects of the invention is that it provides charge-balance power devices having the same charge-balance body region with the same voltage rating regardless of a current rating and a method of manufacturing such charge-balance power devices.

Other advantages of the invention will be easily understood from the following description.

According to an aspect of the invention, there is provided a wafer structure of a charge-balance power device, having a charge-balance body region in which one or more first conductive type pillars of a first conductive type impurity region and one or more second conductive type pillars of a second conductive type impurity region are arranged; and a first conductive type epitaxial layer that is disposed on the charge-balance body region, and said one or more second conductive type pillars arranged in the charge-balance body region are not vertically aligned with said one or more second conductive type wells formed in the transistor region which is formed in the first conductive type epitaxial layer.

The transistor region and the charge-balance body region may be located so as not to come in contact with each other.

The one or more second conductive type wells arranged in the transistor active region may be diffused until they come in contact with the one or more second conductive type pillars in the charge-balance body region.

The one or more first conductive type pillars and the one or more second conductive type pillars may be arranged to form a super-junction structure.

The one or more second conductive type pillars may be arranged in one or more of a stripe pattern, a lattice pattern, a rod pattern with rods inserted into vertexes of a lattice pattern, over the entire area of a wafer for manufacturing the charge-balance power device.

The first conductive type may be one of a P type and an N type and the second conductive type is the other of a P type and an N type.

According to another aspect of the invention, there is provided a charge-balance power device including: a charge-balance body region in which one or more first conductive type pillars of a first conductive type impurity region and one or more second conductive type pillars of a second conductive type impurity region are arranged; a first conductive type epitaxial layer that is formed on the charge-balance body region; and a transistor region that is formed in the first conductive type epitaxial layer.

The one or more second conductive type pillars arranged in the charge-balance body region may be arranged so that they are not vertically aligned with one or more second conductive type wells formed in the transistor region.

The transistor region and the charge-balance body region may be located so as not to come in contact with each other.

One or more second conductive type wells formed in the transistor region may be diffused until they come in contact with the one or more second conductive type pillars arranged in the charge-balance body region.

The one or more first conductive type pillars and the one or more second conductive type pillars may be arranged to form a super-junction structure.

The one or more second conductive type pillars may be arranged in one or more of a stripe pattern, a lattice pattern, a rod pattern with rods inserted into vertexes of a lattice pattern in the entire area of a wafer for manufacturing the charge-balance power device.

The first conductive type may be one of a P type and an N type and the second conductive type is the other of a P type and an N type.

According to another aspect of the invention, there is provided a method of manufacturing a charge-balance power device, including the steps of: forming a charge-balance body region in which one or more first conductive type pillars of a first conductive type impurity region and one or more second conductive type pillars of a second conductive type impurity region are arranged; forming a first conductive type epitaxial layer on the charge-balance body region; and forming a transistor region in the first conductive type epitaxial layer.

The one or more second conductive type pillars arranged in the charge-balance body region may be arranged so that they are not vertically aligned with one or more second conductive type wells formed in the transistor region.

The transistor region and the charge-balance body region may be located so as not to come in contact with each other.

One or more second conductive type wells formed in the transistor active region may be diffused until they come in contact with the one or more second conductive type pillars arranged in the charge-balance body region.

The one or more first conductive type pillars and the one or more second conductive type pillars may be arranged to form a super-junction structure.

The one or more conductive pillars may be arranged in one or more of a stripe pattern, a lattice pattern, a rod pattern with rods inserted into vertexes of a lattice pattern in the entire area of a wafer for manufacturing the charge-balance power device.

The first conductive type may be one of a P type and an N type and the second conductive type is the other of a P type and an N type.

According to the above-mentioned configurations, it is possible to form the same charge-balance body region regardless of the structure of a transistor region formed on the top side of a wafer with the same breakdown voltage.

It is also possible to form the same charge-balance body region regardless of a current rating but with the same voltage rating.

### BRIEF DESCRIPTION OF THE DRAWINGS

FIG. 1 is a sectional view illustrating a charge-balance power device according to the prior art.

FIG. 2 is a sectional view illustrating a charge-balance power device according to an embodiment of the invention.

FIGS. 3A to 3C are diagrams illustrating a charge-balance body region forming method according to embodiments of the invention.

FIG. 4 is a diagram illustrating a state where a chip pattern is formed on the charge-balance body region according to an embodiment of the invention.

FIG. 5 is a flow diagram illustrating a method for manufacturing a charge-balance power device according to an embodiment of the invention.

FIG. 6 is a sectional view illustrating a charge-balance power device according to another embodiment of the invention.

FIGS. 7A to 7C are graphs illustrating characteristic comparison results of the charge-balance power device according to the embodiment of the invention and the charge-balance power device according to the prior art.

### DESCRIPTION OF EXEMPLARY EMBODIMENTS

As the invention can be modified in various ways and practiced in various embodiments, several specific embodiments will be described and shown in the drawings. However, such embodiments are not intended to limit the invention, but it should be understood that the invention includes all modifications, equivalents, and replacements within the concept and the technical scope of the invention. Detailed descriptions of prior art associated with the invention that are deemed not to be helpful in understanding the invention are omitted.

Terms such as “first” and “second” can be used to describe various elements, but the elements are not limited to the terms. Such terms are used only to distinguish one element from another.

The terms used in the following description are used merely to describe specific embodiments, but are not intended to limit the invention. Unless the context clearly requires otherwise, an expression of singular includes an expression of the plural. The terms such as “include” and “have” are intended to indicate that the features, numbers, steps, operations, elements, components, or combinations thereof used in the following description exist and it should be understood that the possibility of existence or addition of one or more different features, numbers, steps, operations, elements, components, or combinations thereof is not excluded.

If an element such as a layer, a region, and a substrate is said to be disposed “on” another element or extends “onto” another element, it should be understood that such element is disposed directly on the other element or extends directly onto the other element, or still another element is interposed therebetween. However, if an element is said to be disposed “directly on” another element or extends “directly onto” another element, it should be understood that no other element is interposed therebetween. If an element is said to be “connected to” or “coupled to” another element, it should be understood that still another element may be interposed therebetween, as well as that the element may be connected or coupled directly to another element. However, if an element is said to be “connected directly to” or “coupled directly to” another element, it should be understood that no other element is interposed therebetween.

Relative terms such as “below”, “above”, “upper”, “lower”, “horizontal”, “lateral”, and “vertical” can be used to describe the relative orientation of an element, a layer, or a region to another element, another layer, or another region as shown in the drawings. Such terms are intended to indicate various directions of a device relative to the orientation shown in the drawings.

The exemplary embodiments of the invention will be described now in detail with reference to the accompanying drawings.

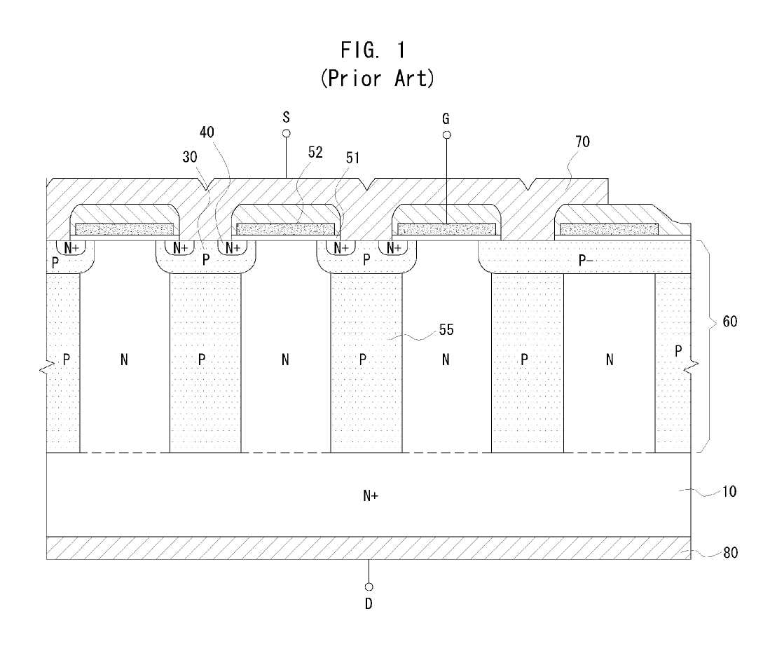

FIG. 1 is a sectional view illustrating a charge-balance power device according to the prior art.

Referring to FIG. 1, a semiconductor device includes a super-junction structure in which N conductive type impurity regions (that is, N-type pillars) and P conductive type impurity regions (that is, P-type pillars) 55 are vertically extended in a semiconductor layer 60 formed on a N+ conductive type semiconductor substrate 10 and are alternately arranged in a horizontal direction. Low-concentration P conductive type wells 30 are formed on the super-junction structure and source regions 40 formed of high-concentration N conductive type impurities are formed in the P conductive type wells 30. Source electrodes 70 are electrically connected to the source regions 40.

P-type pillars are vertically aligned with P conductivity wells 30 in the sense that the center lines of each P-type pillar and the P conductivity well situation over it are approximately aligned.

The semiconductor device includes a gate stack including a gate insulating film 51 and a gate electrode 52 on the top surface of the semiconductor layer over portions of adjacent source regions 40 and the area between such adjacent source regions. The semiconductor substrate 10 is connected to a drain electrode 80.

When the semiconductor device is turned on, the N-type pillars provide a conductive path for electrons flowing from the source electrode to the drain electrode 80 through a channel formed under the gate stack. When the semiconductor device is turned off the N-type pillars and the P-type pillars 55 are depleted due to the reverse bias, thereby providing a satisfactorily high breakdown voltage characteristic.

To manufacture a semiconductor device having the super-junction structure, the N conductive type semiconductor layer 60 is formed on the semiconductor substrate 10 using an epitaxial growth method and trenches are formed in a region in which the P-type pillars 55 should be formed using an etching process. Thereafter, a P conductive type epitaxial layer filling the formed trenches is formed using a chemical vapor deposition method or other methods, thereby forming the super-junction structure in which the N-type pillars and the P-type pillars 55 are alternately arranged.

However, the charge-balance power device according to the prior art shown in FIG. 1 has a shortcoming in that devices having the same breakdown voltage but different current ratings need different charge-balance body regions 60 dependent on the design of the transistor region.

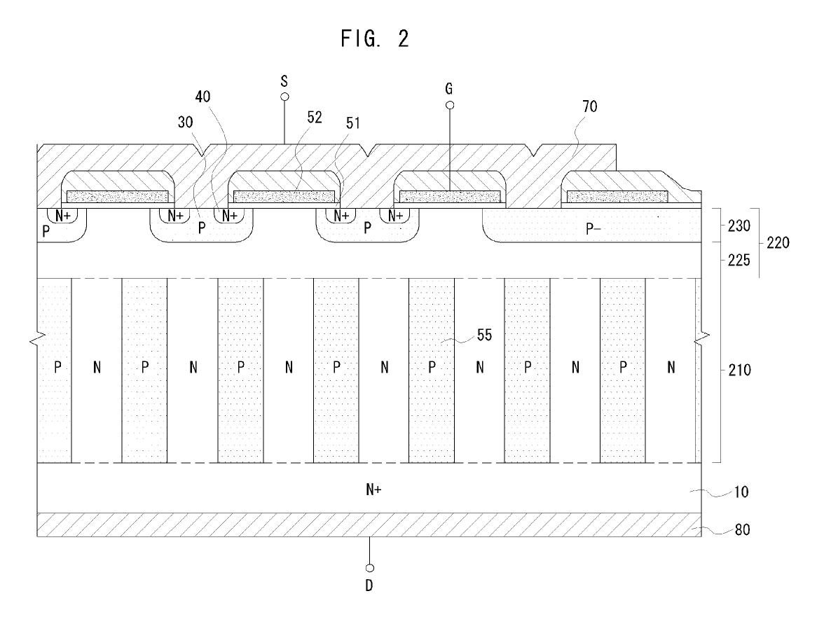

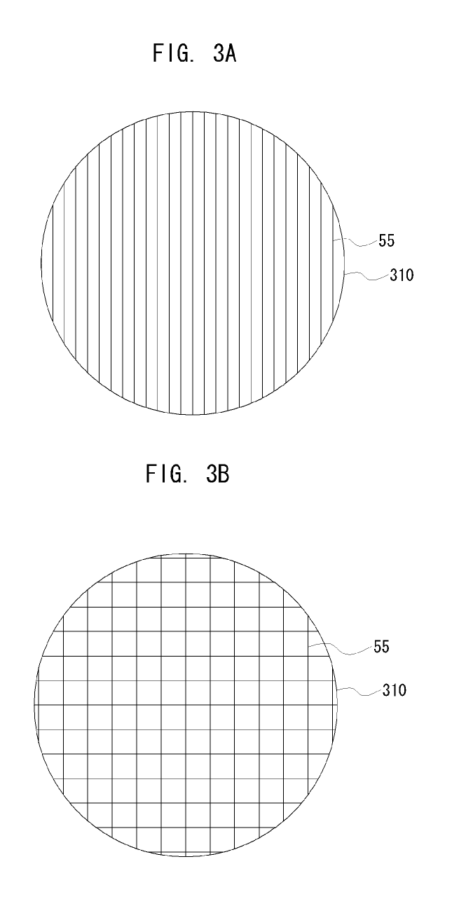

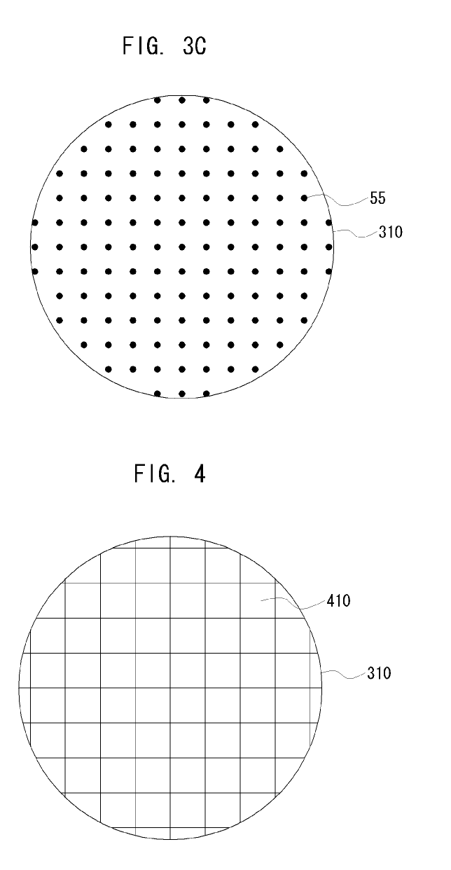

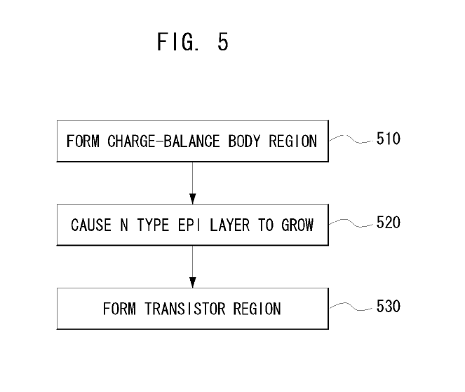

FIG. 2 is a sectional view illustrating a charge-balance power device according to an embodiment of the invention. FIGS. 3A to 3C are diagrams illustrating charge-balance body region forming methods according to various embodiments of the invention. FIG. 4 is a diagram illustrating a state where a chip pattern is formed on the charge-balance body region according to an embodiment of the invention. FIG. 5 is a flow diagram illustrating a method for manufacturing a charge-balance power device according to an embodiment of the invention.

Referring to FIGS. 2 and 5, a semiconductor device includes a charge-balance body region 210 and an N conductive type epitaxial (EPI) layer 220 vertically stacked on an N conductive type semiconductor substrate 10. The N conductive type epitaxial layer 220 can be viewed conceptually as comprising of a separation region 225 and a transistor region 230. A transistor region 230 is formed in the N conductive type epitaxial layer 220 using typical semiconductor manufacturing processes.

The transistor region 230 is formed in the upper portion of the N conductive type epitaxial layer 220 through implantation, diffusion or other processes of P conductive type ions and N conductive type ions.

Although not shown, the semiconductor device may be formed of a P+ conductive type semiconductor substrate.

The charge-balance body region 210 is formed as a super-junction structure in which N conductive type impurity regions (that is, N type pillars) and P conductive type impurity regions (that is, P type pillars) 55 are vertically extending from an N conductive type semiconductor substrate 10 and are alternately arranged in the horizontal direction.

It is assumed in FIG. 2 that the cross sections of the P type pillars and the N type pillars are rectangular, but the invention is not limited to this shape and the P type pillars may have various shapes such as a trapezoidal shape (for example, a tapered shape). For example, when the height of the super-junction structure in the charge-balance body region 210 is in the range of several tens to several hundreds micrometers and the width thereof is several micrometers, it may be difficult to form trenches having exactly vertical sidewalls in the charge-balance body region 210. Various methods other than trench forming method may be used to form the P type pillars and the like.

FIGS. 3A to 3C conceptually illustrate possible arrangements of the charge-balance body region 210 including the P type pillars 55 formed on a wafer 310. For example, the P type pillars 55 may be arranged uniformly over the entire top surface of the wafer 310. That is, the P type pillars 55 may be arranged in the form of evenly spaced parallel straight lines as shown in FIG. 3A, in the form of evenly spaced lattices as shown in FIG. 3B, or in the form of rods inserted into vertexes of a uniform lattice pattern as shown in FIG. 3C. The P type pillars 55 may be arranged in various other patterns.

Referring to FIGS. 2 and 5, an N conductive type epitaxial layer 220 is formed on the charge-balance body region 210.

The transistor region 230 is formed in the upper portion of the N conductive type epitaxial layer 220 using ion implantation and diffusion processes or other processes. The transistor region 230 and the charge-balance body region 210 are separated so as not to come in contact with each other with the separation region 225.

Low-concentration P conductive type wells 30 are formed in the transistor region 230 and a source region 40 formed of high-concentration N conductive type impurities is formed in the upper region of each P conductive type well 30. A source electrode 70 is electrically connected to the source region 40.

Referring to FIG. 4, a pattern 410 of chips including the transistor region 230 and others that are formed on the charge-balance body region 210 and the N conductive type epitaxial layer 220 which are in turn formed on the wafer 310 is conceptually illustrated.

As described above, in the charge-balance power device according to an embodiment of the invention, the N conductive type epitaxial layer 220 is formed on the charge-balance body region 210, the transistor region 230 is formed in the upper portion of the N conductive type epitaxial layer 220, and the charge-balance body region 210 and the transistor region 230 do not come in contact with each other and, in contrast to the prior art device in FIG. 1, need not be vertically aligned That the structures need not be vertically aligned includes the case where the P conductive type wells 30 formed in the transistor region 230 and the P type pillars 55 of the charge-balance body region 210 are not aligned with each other at all, and also includes the cases where some P conductive type wells 30 and some P type pillars 55 of the charge-balance body region 210 are vertically aligned.

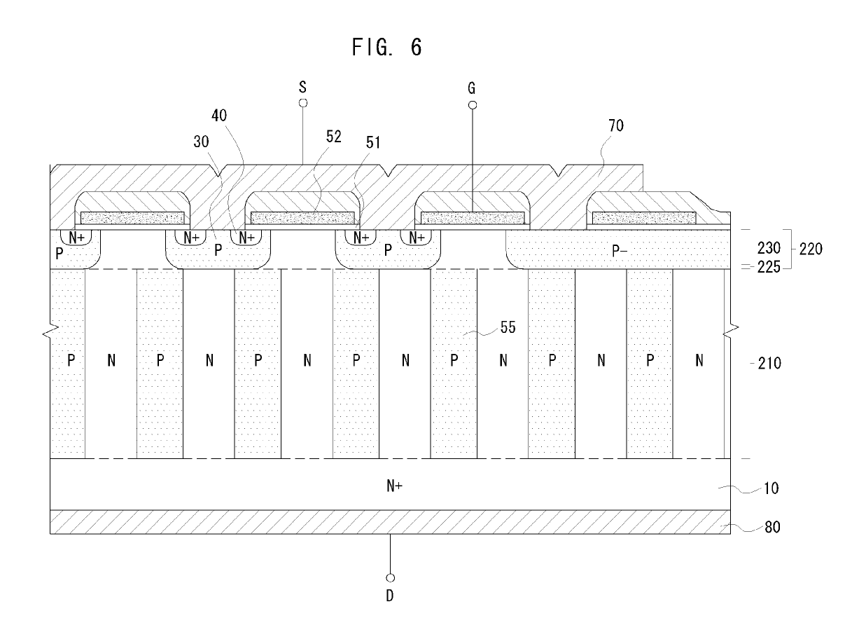

FIG. 6 is a sectional view illustrating a charge-balance power device according to another embodiment of the invention.

Referring to FIG. 6, in the semiconductor device, a charge-balance body region 210 and an N conductive type epitaxial (EPI) layer 220 are formed on an N conductive type semiconductor substrate 10 in the vertical direction, and a transistor region 230 is formed in the N conductive type epitaxial layer 220 using typically semiconductor manufacturing processes.

However, unlike the sectional structure of the semiconductor device described with reference to FIG. 2, it can be seen from the sectional structure of the semiconductor device shown in FIG. 6 that the charge-balance body region 210 and the transistor region 230 come in contact with each other.

The contact occurs because the thickness of the separation region 225 is relatively small and, during heat treatment and other processes in forming the transistor region 230 in the N conductive type epitaxial region 220, the P conductive type ions for forming the P conductive type wells 30 of the transistor region 230 are diffused until coming in contact with the P type pillars 55 in the charge-balance body region 210.

However, even in this case, the charge-balance body region 210 and the transistor region 230 need not be vertically aligned with each other, unlike the prior art described with reference to FIG. 1. That the structure need not be vertical aligned includes the case where the P conductive type wells 30 formed in the transistor region 230 and the P type pillars 55 of the charge-balance body region 210 are not aligned with each other at all, and also includes the cases where some P conductive type wells 30 and some P type pillars 55 of the charge-balance body region 210 are vertically aligned.

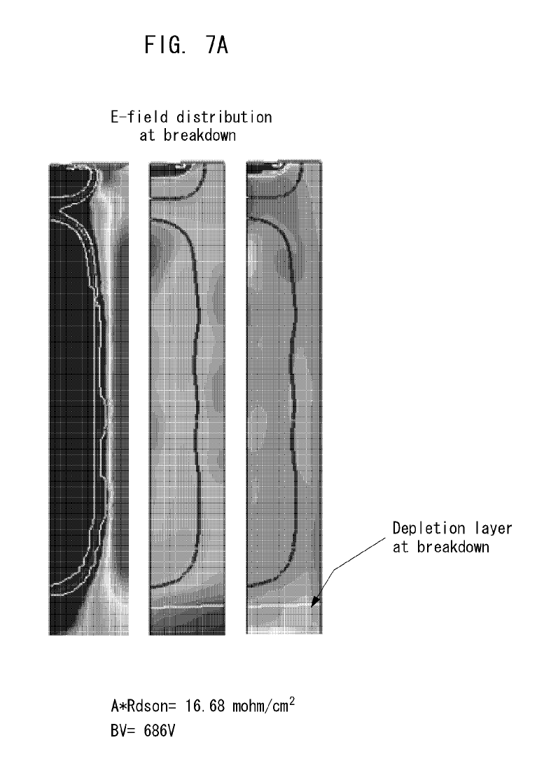

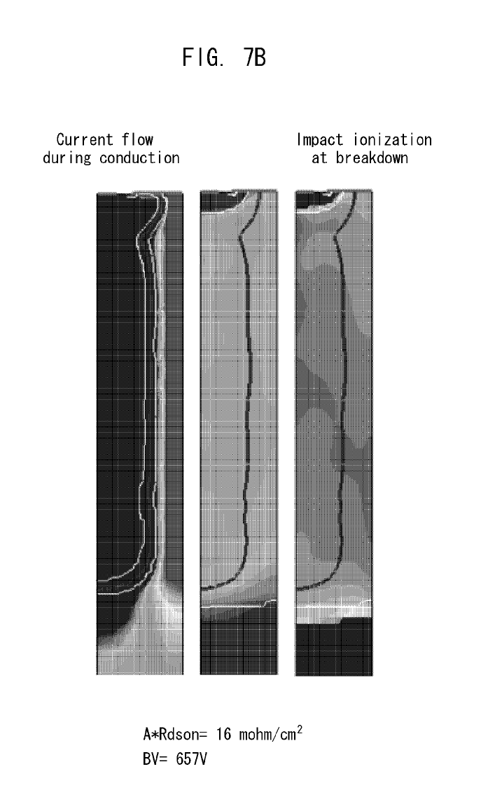

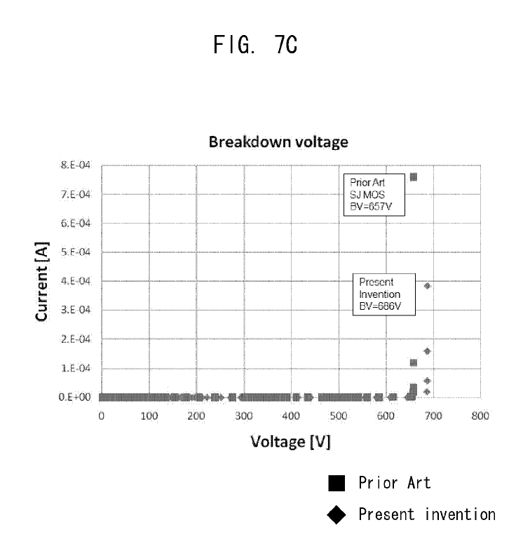

FIGS. 7A to 7C are graphs illustrating characteristic comparison results of the charge-balance power device according to an embodiment of the invention and a charge-balance power device according to the related art.

FIG. 7A is a graph illustrating on-resistance (Rds.on) and withstanding voltage characteristics of the charge-balance power device (600 V class) according to an embodiment of the invention, FIG. 7B is a graph illustrating on-resistance (Rds.on) and withstanding voltage characteristics of the charge-balance power device (600 V class) according to the prior art, and FIG. 7C is a graph illustrating breakdown voltage characteristics of a charge-balance power device according to an embodiment of the invention and a device according to the prior art.

As can be seen from the graphs, the charge-balance power device according to an embodiment of the invention exhibits approximately the same breakdown voltage while providing other characteristics that are equivalent to or improved from those of the charge-balance power device according to the prior art.

While the invention is described with reference to one or more embodiments, it will be understood by those skilled in the art that the invention can be modified and changed in various forms without departing from the spirit and scope of the invention described in the appended claims.

What is claimed is:

1. A wafer structure of a charge-balance power device, comprising:
a charge-balance body region in which one or more first conductive type pillars as a first conductive type impurity region and one or more second conductive type pillars as a second conductive type impurity region are arranged; and
a first conductive type epitaxial layer that is disposed on the charge-balance body region,
wherein the one or more second conductive type pillars arranged in the charge-balance body region are not vertically aligned with one or more second conductive type wells formed in a transistor region which is formed in the first conductive type epitaxial layer.

2. The wafer structure according to claim 1, wherein the transistor region and the charge-balance body region are located so as not to come in contact with each other.

3. The wafer structure according to claim 1, wherein the one or more second conductive type wells arranged in the transistor region come in contact with the one or more second conductive type pillars arranged in the charge-balance body region.

4. The wafer structure according to claim 1, wherein the one or more first conductive type pillars and the one or more second conductive type pillars constitute a super-junction structure.

5. The wafer structure according to claim 1, wherein the one or more second conductive type pillars are arranged in one or more patterns of a stripe pattern, a lattice pattern, a rod pattern with rods inserted into vertexes of a lattice pattern in the entire area of a wafer for manufacturing the charge-balance power device.

6. The wafer structure according to claim 1, wherein the first conductive type is one of a P type and an N type and the second conductive type is the other of a P type and an N type.

7. A charge-balance power device comprising:
a charge-balance body region in which one or more first conductive type pillars as a first conductive type impurity region and one or more second conductive type pillars as a second conductive type impurity region are arranged;
a first conductive type epitaxial layer that is formed on the charge-balance body region; and
a transistor region that is formed in the first conductive type epitaxial layer.
wherein the one or more second conductive type pillars arranged in the charge-balance body region are not vertically aligned with one or more second conductive type wells formed in the transistor region.

8. The charge-balance power device according to claim 7, wherein the transistor region and the charge-balance body region are located so as not to come in contact with each other.

9. The charge-balance power device according to claim 7, wherein one or more second conductive type wells formed in the transistor region come in contact with the one or more second conductive type pillars arranged in the charge-balance body region.

10. The charge-balance power device according to claim 7, wherein the one or more first conductive type pillars and the one or more second conductive type pillars constitute a super-junction structure.

11. The charge-balance power device according to claim 7, wherein the one or more second conductive type pillars are arranged in one or more patterns of a stripe pattern, a lattice pattern, a rod pattern with rods inserted into vertexes of a lattice pattern in the entire area of a wafer for manufacturing the charge-balance power device.

12. The charge-balance power device according to claim 7, wherein the first conductive type is one of a P type and an N type and the second conductive type is the other of a P type and an N type.

13. A method of manufacturing a charge-balance power device, comprising:
forming a charge-balance body region in which one or more first conductive type pillars as a first conductive type impurity region and one or more second conductive type pillars as a second conductive type impurity region are arranged;
forming a first conductive type epitaxial layer on the charge-balance body region; and
forming a transistor region in the first conductive type epitaxial layer.

14. The method according to claim 13, wherein the one or more second conductive type pillars arranged in the charge-balance body region are not vertically aligned with one or more second conductive type wells formed in the transistor region.

15. The method according to claim 13, wherein the transistor region and the charge-balance body region are located so as not to come in contact with each other.

16. The method according to claim 13, wherein one or more second conductive type wells formed in the transistor region come in contact with the one or more second conductive type pillars arranged in the charge-balance body region.

17. The method according to claim 13, wherein the one or more first conductive type pillars and the one or more second conductive type pillars constitute a super-junction structure.

18. The method according to claim 13, wherein the one or more second conductive type pillars are arranged in one or more patterns of a stripe pattern, a lattice pattern, a rod pattern with rods inserted into vertexes of a lattice pattern in the entire area of a wafer for manufacturing the charge-balance power device.

19. The method according to claim 13, wherein the first conductive type is one of a P type and an N type and the second conductive type is the other of a P type and an N type.
